(19) United States
(12) Patent Application Publication
(10) Pub. No.: US 2025/0390015 A1
(43) Pub. Date: Dec. 25, 2025

(54) PHOTOMASK AND METHOD FOR TRANSFERRING PATTERN

(71) Applicant: UNITED MICROELECTRONICS CORP., Hsin-Chu City (TW)

(72) Inventors: Wei-Xun Chen, Nantou County (TW); Yi-Chieh Lai, Nantou County (TW); Sheng-Jhe Gao, Tainan City (TW)

(73) Assignee: UNITED MICROELECTRONICS CORP., Hsin-Chu City (TW)

(21) Appl. No.: 18/789,726

(22) Filed: Jul. 31, 2024

(30) Foreign Application Priority Data
Jun. 20, 2024 (TW) 113122961

(51) Int. Cl. G03F 1/44; G03F 7/00

(52) U.S. Cl. CPC G03F 1/44; G03F 7/70591

(57) ABSTRACT

A photomask configured to corporate with an exposure source to pattern a semiconductor device. The semiconductor device defines a first device region and a memory region disposed adjacent to the first device region, and the semiconductor device includes a memory device disposed in the memory region. The photomask includes a base, a predetermined pattern and a first optical assist member. The base defines a first pattern region and a second pattern region respectively corresponding to the first device region and the memory region. The predetermined pattern is disposed in the first pattern region. The first optical assist member is disposed in the second pattern region. A pattern density of the first pattern region is greater than a pattern density of the second pattern region, and a dimension of the first optical assist member is less than an exposure limit of the exposure source.

### BACKGROUND OF THE INVENTION

### 1. Field of the Invention

The present disclosure relates to the field of semiconductor devices, and more particularly, to a photomask favorable for accurately transferring a pattern and a method for transferring a pattern using the same.

### 2. Description of the Prior Art

In the field of semiconductor, the photolithography process is widely used to form characteristic patterns in film layers of semiconductor devices. It is known that the photolithography process includes forming a characteristic pattern on a photomask, transferring the characteristic pattern on the photomask to a photoresist layer disposed on a target material layer through an exposure process, so as to form a patterned photoresist on the target material layer, and then the characteristic pattern on the photomask is transferred to the target material layer with the patterned photoresist being an etching mask.

However, based on different arrangements in different regions of the semiconductor device, the pattern densities of the photomask corresponding to different regions are also different. As a result, it difficult for the conditions of the exposure process to satisfy different regions at the same time. Therefore, pattern transfer distortion often occurs at the periphery of each of the regions, and the performance and/or yield of semiconductor devices formed later are affected thereby.

### SUMMARY OF THE INVENTION

According to one aspect of the present disclosure, a photomask configured to corporate with an exposure source to pattern a semiconductor device. The semiconductor device defines a first device region and a memory region disposed adjacent to the first device region, and the semiconductor device includes a memory device disposed in the memory region. The photomask includes a base, a predetermined pattern and a first optical assist member. The base defines a first pattern region and a second pattern region respectively corresponding to the first device region and the memory region. The predetermined pattern is disposed in the first pattern region. The first optical assist member is disposed in the second pattern region. A pattern density of the first pattern region is greater than a pattern density of the second pattern region, and a dimension of the first optical assist member is less than an exposure limit of the exposure source.

According to another aspect of the present disclosure, a method for transferring a pattern includes steps as follows. A semiconductor device defining a first device region and a memory region disposed adjacent to the first device region is provided. The semiconductor device includes a memory device and a target material layer. The memory device is disposed in the memory region. The target material layer is disposed in the first device region and the memory region, and the target material layer is located above the memory device. A photoresist layer is formed on the target material layer. A photomask is provided between the photoresist layer and an exposure source. The photomask includes a base, a predetermined pattern and a first optical assist member. The base defines a first pattern region and a second pattern region respectively corresponding to the first device region and the memory region. The predetermined pattern is disposed in the first pattern region, and the first optical assist member is disposed in the second pattern region. A pattern density of the first pattern region is greater than a pattern density of the second pattern region. A dimension of the first optical assist member is less than an exposure limit of the exposure source.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic top view showing a semiconductor device according to an embodiment of the present disclosure.

FIG. 2 is a schematic cross-sectional view showing a step of a method for transferring a pattern according to an embodiment of the present disclosure.

FIG. 3 is a schematic cross-sectional view showing another step of the method for transferring the pattern according to the embodiment of the present disclosure.

FIG. 4 is a schematic view showing an arrangement of an exposure source, a photomask and the semiconductor device according to an embodiment of the present disclosure.

FIG. 5 is a schematic top view showing the photomask according to an embodiment of the present disclosure.

FIG. 6 is a schematic cross-sectional view showing further another step of the method for transferring the pattern according to the embodiment of the present disclosure.

FIG. 7 is a schematic cross-sectional view showing yet another step of the method for transferring the pattern according to the embodiment of the present disclosure.

FIG. 8 is a schematic top view showing a photomask according to another embodiment of the present disclosure.

FIG. 9 is a schematic cross-sectional view showing a step of a method for transferring a pattern according to another embodiment of the present disclosure.

FIG. 10 is a schematic cross-sectional view showing a semiconductor device obtained by using a conventional photomask to transfer a pattern.

### DETAILED DESCRIPTION

In the following detailed description of the embodiments, reference is made to the accompanying drawings which form a part thereof, and in which is shown by way of illustration specific embodiments in which the disclosure may be practiced. In this regard, directional terminology, such as up, down, left, right, front, back, bottom or top is used with reference to the orientation of the Figure(s) being described. The elements of the present disclosure can be positioned in a number of different orientations. As such, the directional terminology is used for purposes of illustration and is in no way limiting. In addition, identical reference signs or similar reference signs are used for identical elements or similar elements in the following embodiments.

Hereinafter, for the description of “the first feature is formed on or above the second feature”, it may refer that “the first feature is in contact with the second feature directly”, or it may refer that “there is another feature between the first feature and the second feature”, such that the first feature is not in contact with the second feature directly.

It is understood that, although the terms first, second, etc. may be used herein to describe various elements, regions, layers and/or sections, these elements, regions, layers and/or sections should not be limited by these terms. These terms may be only used to distinguish one element, region, layer and/or section from another element, region, layer and/or section. Terms such as “first,” “second,” and other numerical terms when used herein do not imply a sequence or order unless clearly indicated by the context. Thus, a first element, region, layer and/or section discussed below could be termed a second element, region, layer and/or section without departing from the teachings of the embodiments. The terms used in the claims may not be identical with the terms used in the specification, but may be used according to the order of the elements claimed in the claims.

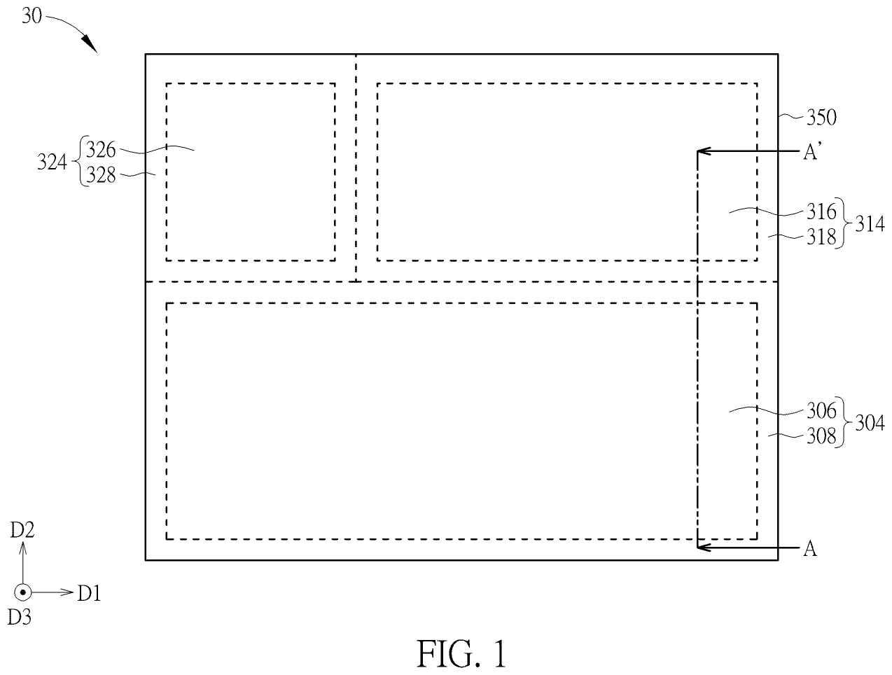

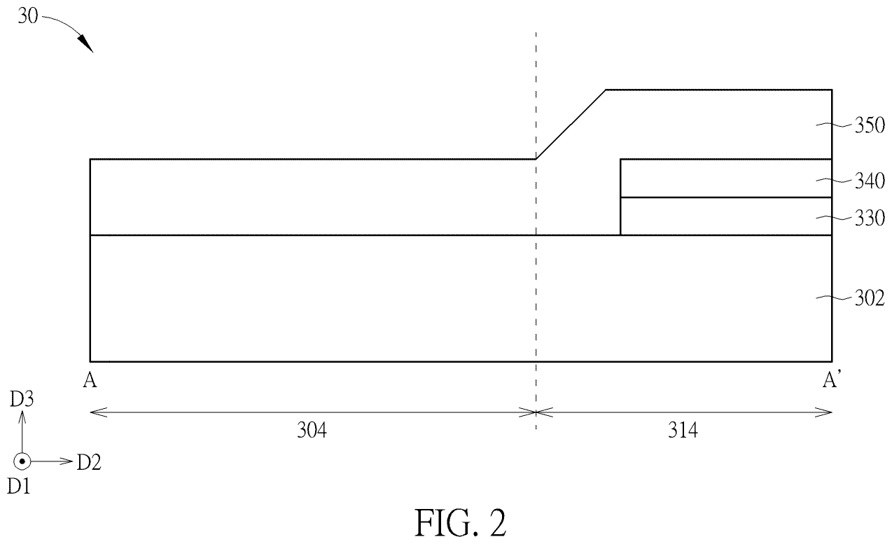

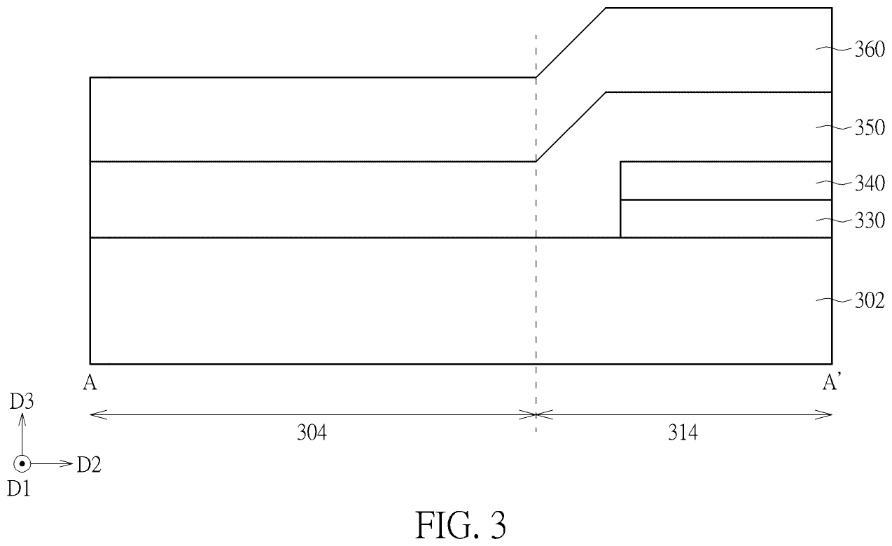

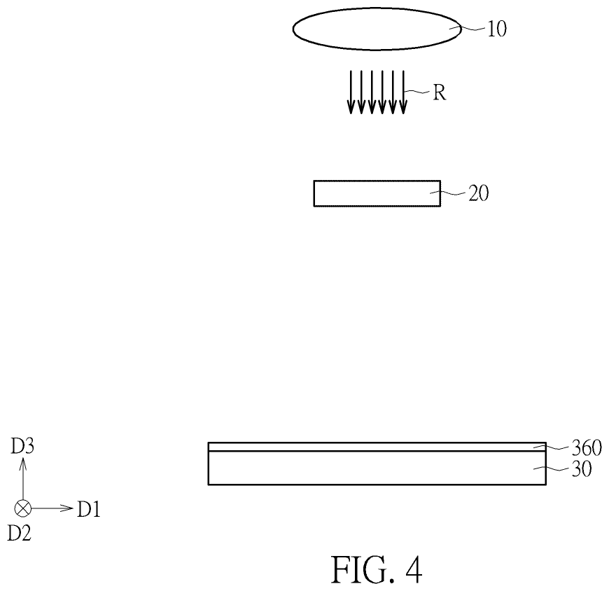

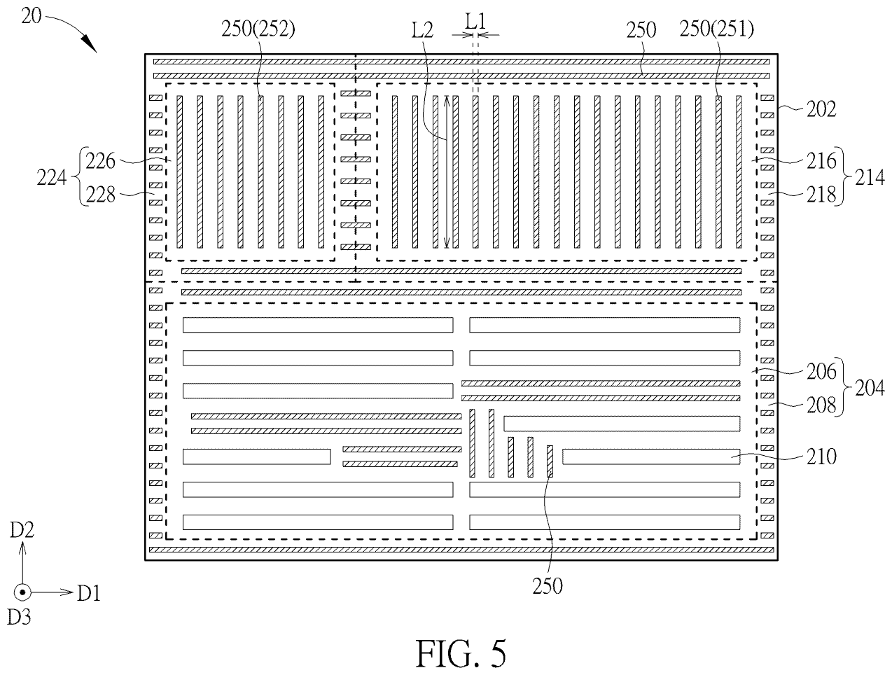

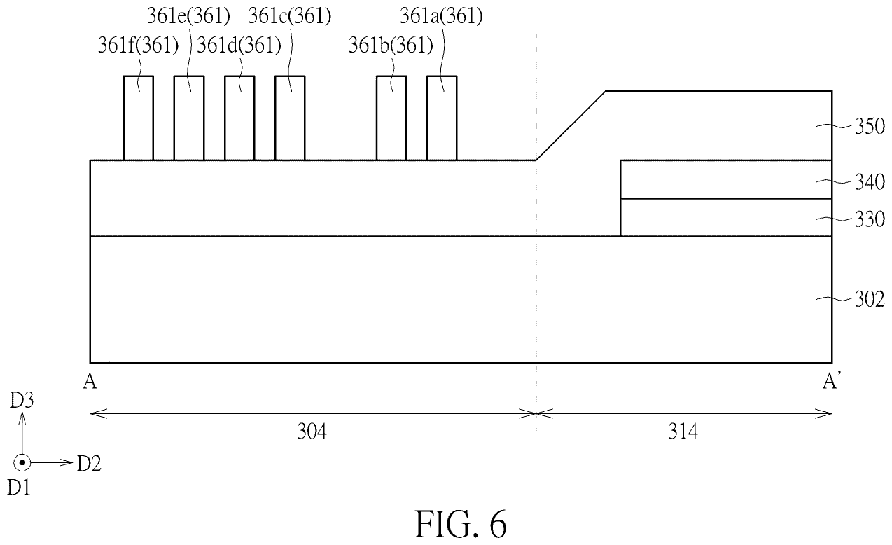

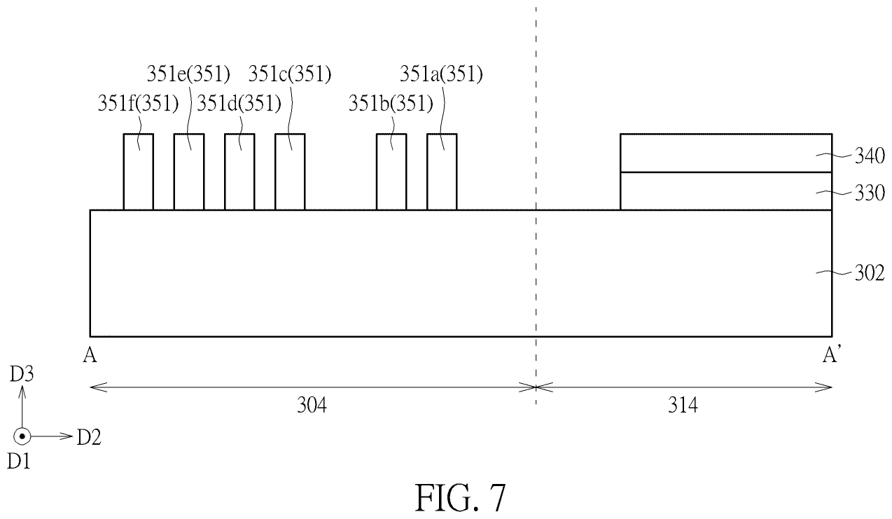

Please refer to FIG. 1 to FIG. 7. FIG. 1 is a schematic top view showing a semiconductor device 30 according to an embodiment of the present disclosure. FIG. 2, FIG. 3, FIG. 6 and FIG. 7 are schematic cross-sectional views showing steps of a method for transferring a pattern according to an embodiment of the present disclosure, the viewing angles thereof are corresponding to the line A-A′ in FIG. 1. FIG. 4 is a schematic view showing an arrangement of an exposure source 10, a photomask 20 and the semiconductor device 30 according to an embodiment of the present disclosure. FIG. 5 is a schematic top view showing the photomask 20 according to an embodiment of the present disclosure. According to the present disclosure, a method for transferring a pattern includes steps as follows. First, the semiconductor device 30 is provided. As shown in FIG. 1 and FIG. 2, the semiconductor device 30 includes a substrate 302. The substrate 302 may be a silicon substrate, an epitaxial silicon substrate, a silicon carbide substrate or a silicon on insulator (SOI) substrate. The substrate 302 of the semiconductor device 30 defines a first device region 304 and a memory region 314, and may optionally define a second device region 324. The memory region 314 is disposed adjacent to the first device region 304, and the second device region 324 is disposed adjacent to the first device region 304. Specifically, the first device region 304 and the memory region 314 are disposed adjacent to each other along a horizontal direction D2, the first device region 304 and the second device region 324 are disposed adjacent to each other along the horizontal direction D2, and the second device region 324 and the memory region 314 are disposed adjacent to each other along a horizontal direction D1. The horizontal direction D1 and the horizontal direction D2 are perpendicular to each other. However, the present disclosure is not limited thereto. The number and the arrangement of the first device region 304, the memory region 314 and the second device region 324 shown in FIG. 1 are only exemplary, and may be adjusted according to actual needs.

The semiconductor device 30 further includes a memory device 330 and a target material layer 350, and may optionally include a mask layer 340. The memory device 330 is disposed in the memory region 314. The mask layer 340 is disposed on the memory device 330, and the target material layer 350 covers the substrate 302 completely. That is, the target material layer 350 is disposed in the first device region 304, the memory region 314 and the second device region 324, and the target material layer 350 is located above the memory device 330.

The memory device 330 may be, for example, an embedded flash memory (eFlash memory) device. At this stage, the memory device 330 protrudes relative to a surface of the semiconductor device 30. Herein, the memory device 330 exemplarily protrudes relative to a top surface (not labeled) of the substrate 302 in a vertical direction D3. The vertical direction D3, for example, may be perpendicular to the top surface of the substrate 302. The target material layer 350 substantially follows the morphology of the memory device 330, and a portion of the target material layer 350 in the memory region 314 protrudes relative to a portion of the target material layer 350 in the first device region 304. In order to simplify the drawing, the memory device 330 shown in FIG. 2 is represented by a single device, but not limited thereto. For example, the memory device 330 may include a plurality of memory cells (not shown), and the plurality of memory cells may be arranged along the horizontal directions D1 and D2 to form an array, such as a rectangular array, but not limited thereto. The number and arrangement of the memory cells may be adjusted according to actual needs, and the shape of the array is adjusted accordingly.

The target material layer 350 is the film layer of the semiconductor device 30 desired to be patterned. The mask layer 340 covers the memory device 330. The mask layer 340 is configured to protect the memory device 330 and prevent the memory device 330 from being damaged in the subsequent process of patterning the target material layer 350. The mask layer 340 may include a nitride, but not limited thereto.

The first device region 304 may be a low voltage device region, and the second device region 324 may be a medium and high voltage device region. The low voltage device region is configured to dispose low voltage devices, such as devices with an operation voltage less than or equal to 5 volts, or devices with an operation voltage less than or equal to 1.5 volts. The medium and high voltage device region is configured to dispose medium and high voltage devices, such as devices with an operation voltage greater than 5 volts or devices with an operation voltage greater than 10 volts. Taking a display chip as an example, the low voltage device region may include logic operation circuits, and the medium and high voltage device region may include driving devices.

Since the devices disposed in the first device region 304, the memory region 314 and the second device region 324 are different, the devices in different regions may be fabricated at different stages. In this embodiment, patterning the target material layer 350 is for fabricating devices of the first device region 304. That is, the remaining portion of the target material layer 350 after the patterning process is reserved in the first device region 304, while the portions of the target material layer 350 in the memory region 314 and the second device region 324 are required to be removed. According to an embodiment of the present disclosure, the target material layer 350 includes a non-metallic gate material, such as polysilicon, and patterning the target material layer 350 is for fabricating the gate of the first device region 304. Before patterning the target material layer 350, the fabrication of the memory device 330 in the memory region 314 is completed. Similarly, before patterning the target material layer 350, the fabrication of medium and high voltage devices (not shown) in the second device region 324 may also be completed. In addition, the semiconductor device 30 may optionally include another mask layer (not shown) to cover and protect the medium and high voltage devices in the second device region 324.

Next, as shown in FIG. 3, a photoresist layer 360 is formed on the target material layer 350. Next, as shown in FIG. 4, the photomask 20 is provided between the photoresist layer 360 and the exposure source 10. The exposure source 10 is configured to provide exposure light rays R, and the photomask 20 is located in the optical path of the exposure light rays R. The exposure source 10 may be a deep ultraviolet (DUV) light source. For example, the exposure source 10 may be a krypton fluoride (KrF) excimer laser, and a wavelength of the exposure light rays R is about 248 nanometers. As another example, the exposure source 10 may be an argon fluoride (ArF) excimer laser, and a wavelength of the exposure light rays R is about 193 nanometers, but not limited thereto. In some embodiments, the exposure source 10 may be an ultraviolet (UV) light source or an extreme ultraviolet (EUV) light source.

Please refer to FIG. 5, the photomask 20 includes a base 202. The base 202 defines a first pattern region 204 and a second pattern region 214 respectively corresponding to the first device region 304 and the memory region 314. When the semiconductor device 30 defines a second device region 324, the photomask 20 may further define a third pattern region 224 corresponding to the second device region 324. Specifically, the first pattern region 204 and the second pattern region 214 are disposed adjacent to each other along the horizontal direction D2, the first pattern region 204 and the third pattern region 224 are disposed adjacent to each other along the horizontal direction D2, and the third pattern region 224 and the second pattern region 214 are disposed adjacent to each other along the horizontal direction D1. However, the present disclosure is not limited thereto. The number and arrangement of the first pattern region 204, the second pattern region 214 and the third pattern region 224 may be flexibly adjusted according to the number and arrangement of the first device region 304, the memory region 314 and the second device region 324.

The photomask 20 further includes predetermined patterns 210 and optical assist members 250. The predetermined patterns 210 are disposed in the first pattern region 204, and the optical assist members 250 are disposed in the second pattern region 214 and the third pattern region 224. A pattern density of the first pattern region 204 is greater than a pattern density of the second pattern region 214, the pattern density of the first pattern region 204 is greater than a pattern density of the third pattern region 224, and a dimension of each of the optical assist members 250 is less than an exposure limit of the exposure source 10. The predetermined patterns 210 are patterns that are desired to be transferred to the photoresist layer 360 and the target material layer 350, and the patterns of the optical assist members 250 are not desired to be transferred to the photoresist layer 360 and the target material layer 350. With the dimension of each of the optical assist members 250 being less than the exposure limit of the exposure source 10, the patterns of the optical assist members 250 can be prevented from being transferred to the photoresist layer 360 and the target material layer 350. Moreover, the dimension of each of the predetermined patterns 210 is required to be greater than the exposure limit of the exposure source 10.

The material of the base 202 may include transparent materials, such as quartz, but not limited thereto. The materials of the predetermined patterns 210 and the optical assist members 250 may include opaque materials, such as chromium. According to an embodiment of the present disclosure, the predetermined patterns 210 and the optical assist members 250 may be chromium metal layers disposed on the base 202, but not limited thereto.

Next, an exposure and development process is performed, wherein the predetermined patterns 210 of the photomask 20 are transferred to the photoresist layer 360. As shown in FIG. 6, patterned photoresists 361 may be formed on the target material layer 350, and the pattern transfer is completed. As shown in FIG. 6, the patterned photoresists 361 are disposed in the first device region 304 but not disposed in the memory region 314. Moreover, the patterned photoresists 361 are not disposed in the second device region 324 (not shown).

Next, the target material layer 350 located below the patterned photoresists 361 is patterned with the patterned photoresists 361 being the etching masks. As shown in FIG. 7, the patterned target materials 351 can be formed in the first device region 304, so that the predetermined patterns 210 of the photomask 20 are transferred to the target material layer 350. As shown in FIG. 7, the patterned target materials 351 are disposed in the first device region 304 but not disposed in the memory region 314. Moreover, the patterned target materials 351 are not disposed in the second device region 324. As mentioned above, in this embodiment, patterning the target material layer 350 is for fabricating the gates of the first device region 304. Therefore, the patterned target materials 351 are gates disposed in the first device region 304. Although not shown in the drawings, transistor processes, such as forming spacers and the source/drain regions, may be performed to form transistors in the first device region 304 according to actual needs.

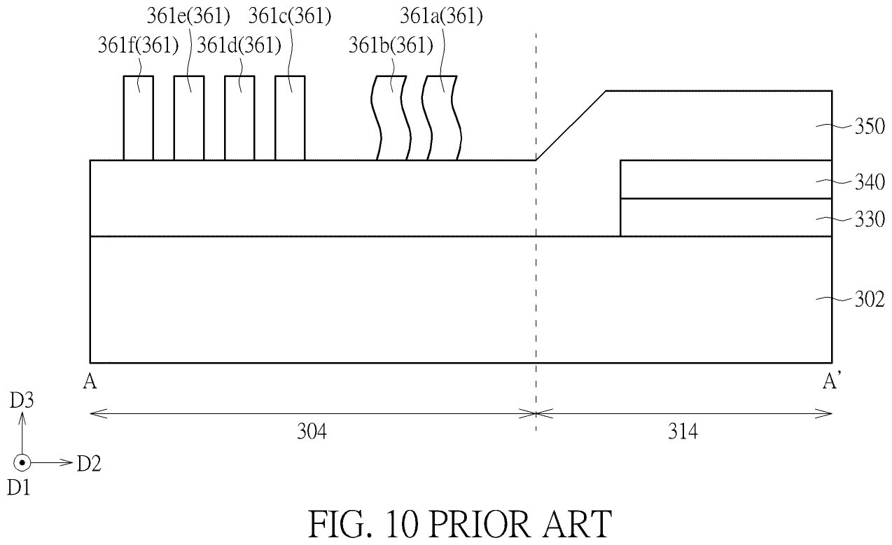

Since patterning the target material layer 350 is for forming the gates of the first device region 304, the portions of the target material layer 350 in the memory region 314 and the second device region 324 are required to be removed. In a conventional photomask (not shown), the second pattern region and the third pattern region are not arranged with any patterns, so that the patterned photoresists 361 can be prevented from being formed in the memory region 314 and the second device region 324. Thereby, the patterned target materials 351 can be prevented from being formed in the memory region 314 and the second device region 324. However, when the conventional photomask is used to transfer the predetermined patterns thereof to the photoresist layer 360, the transmittance of the first pattern region is quite different from the transmittances of the second pattern region and the third pattern region due to the second pattern region and the third pattern region of the conventional photomask without any patterns. As a result, the exposure condition of the portion of the photoresist layer 360 in the first device region 304 close to the memory region 314 and the second device region 324 is different from the exposure condition of the portion of the photoresist layer 360 in the first device region 304 away from the memory region 314 and the second device region 324, so that the pattern transfer distortion tends to occur in the patterned photoresist 361 in the portion of the first device region 304 close to the memory region 314 and the second device region 324. Please refer to FIG. 10, which is a schematic cross-sectional view showing a semiconductor device obtained by using a conventional photomask to transfer a pattern, which corresponds to the process stage of FIG. 6. As shown in FIG. 10, the sidewalls of the patterned photoresists 361a and 361b closer to the memory region 314 distort, while the sidewalls of the patterned photoresists 361c, 361d, 361e and 361f farther from the memory region 314 are straighter. As a result, the defects of the patterned photoresists 361a and 361b are transferred to the target material layer 350, so that the patterned target materials 351a and 351b will inherit the defects of the patterned photoresists 361a and 361b, and the patterned target materials 351c, 351d, 351e and 351f have more accurate pattern transfer effects.

In the present disclosure, with the optical assist members 250 being disposed in the second pattern region 214 and the third pattern region 224 of the photomask 20, the difference between the transmittance of the first pattern region 204 and the transmittance of the second pattern region 214 and the difference between the transmittance of the first pattern region 204 and the transmittance of the third pattern region 224 can be reduced. Thereby, the pattern transfer distortion of the patterned photoresists 361 (such as the patterned photoresists 361a and 361b) close to the memory region 314 and the second device region 324 can be improved significantly, and the pattern transfer distortion of the patterned target materials (such as the patterned target materials 351a and 351b) close to the memory region 314 and the second device region 324 can be improved accordingly. Thereby, the performance and/or yield of the semiconductor device 30 can be improved significantly, while the patterns of the optical assist members 250 can be prevented from being transferred to the photoresist layer 360.

In the photomask 20, the base 202 may have an initial transmittance T0, the first pattern region 204 may have a transmittance T1, the second pattern region 214 may have a transmittance T2, and the third pattern region 224 may have transmittance T3. The aforementioned “the pattern density of the first pattern region 204 is greater than the pattern density of the second pattern region 214” may refer that the transmittance T1 of the first pattern region 204 is less than the transmittance T2 of the second pattern region 214. Similarly, the aforementioned “the pattern density of the first pattern region 204 is greater than the pattern density of the third pattern region 224” may refer that the transmittance T1 of the first pattern region 204 is less than the transmittance T3 of the third pattern region 224. In other words, in the present disclosure, when the pattern density of one pattern region is greater than the pattern density of another pattern region, it may refer that the transmittance of the one pattern region is less than the transmittance of the another pattern region.

According to an embodiment of the present disclosure, the first pattern region 204 may have a transmittance T1, the second pattern region 214 may have a transmittance T2, and the following condition may be satisfied: 1<T2/T1≤1.15. Thereby, the difference between the transmittance T1 of the first pattern region 204 and the transmittance T2 of the second pattern region 214 is smaller, which is beneficial for improving the pattern transfer distortion of the patterned photoresists 361 (such as the patterned photoresists 361a and 361b) close to the memory region 314. Similarly, the first pattern region 204 may have a transmittance T1, the third pattern region 224 may have a transmittance T3, and the following condition may be satisfied: 1<T3/T1≤1.15.

According to an embodiment of the present disclosure, the base 202 may have an initial transmittance T0, the second pattern region 214 may have a transmittance T2, and the following condition may be satisfied: 20%≤T0−T2≤30%. Thereby, the accuracy of pattern transfer of the patterned photoresists 361 (such as the patterned photoresists 361a and 361b) close to the memory region 314 caused by an excessive high transmittance T2 of the second pattern region 214 can be prevented. For example, the initial transmittance T0 can be 100%, and the transmittance T2 can satisfied the following condition: 70%≤T2≤80%. Similarly, the third pattern region 224 may have a transmittance T3, which may satisfy the following condition: 20%≤T0−T3≤30%, and/or may satisfy the following condition: 70%≤T3≤80%.

The aforementioned “a dimension of each of the optical assist members 250 is less than an exposure limit of the exposure source 10” may refer that the length of each of the optical assist member 250 in one direction is less than the exposure limit of the exposure source 10. For example, in FIG. 5, each of the optical assist members 251 in the main pattern portion 216 of the second pattern region 214 has a long strip shape. One of the optical assist members 251 extends along the horizontal direction D2. The optical assist member 251 has a length L1 in the horizontal direction D1 and a length L2 in the horizontal direction D2, and the length L2 is greater than the length L1. As long as the length L1 of the shorter side of the optical assist member 251 is less than the exposure limit of the exposure source 10, the pattern of the optical assist member 251 can be prevented from being transferred to the photoresist layer 360 and the target material layer 350. According to an embodiment of the present disclosure, the length L1 of the optical assist member 251 in the horizontal direction D1 is greater than 0 and less than or equal to 24 nm, but not limited thereto. The length L1 may be flexibly adjusted according to the type of the exposure source 10.

Please refer to FIG. 1. In the semiconductor device 30, the first device region 304 may be further divided into a main device portion 306 and a peripheral portion 308, and the peripheral portion 308 surrounds the main device portion 306. The memory region 314 may be further divided into a main device portion 316 and a peripheral portion 318, and the peripheral portion 318 surrounds the main device portion 316. The second device region 324 may be further divided into a main device portion 326 and a peripheral portion 328, and the peripheral portion 328 surrounds the main device portion 326. The main device portions 306, 316 and 326 are regions of the first device region 304, the memory region 314 and the second device region 324 to disposed predetermined devices. For example, the memory device 330 is disposed in the main device portion 316 but not disposed in the peripheral portion 318.

Please refer to FIG. 5. In the photomask 20, the first pattern region 204 may be further divided into a main pattern portion 206 and a peripheral portion 208 respectively corresponding to the main device portion 306 and the peripheral portion 308 of the first device region 304. The peripheral portion 208 surrounds the main pattern portion 206, and the pattern density of the main pattern portion 206 is greater than the pattern density of the peripheral portion 208.

Specifically, when the first pattern region 204 includes both the main pattern portion 206 and the peripheral portion 208, the predetermined patterns 210 are disposed in the main pattern portion 206 but not disposed in the peripheral portion 208. In addition, the aforementioned transmittance T1 of first pattern region 204 refers to the transmittance of the main pattern portion 206. Since the predetermined patterns 210 are disposed in the main pattern portion 206 but not disposed in the peripheral portion 208, the optical assist members 250 are also disposed in the peripheral portion 208 for adjusting the transmittance of the peripheral portion 208, so as to prevent the peripheral portion 208 from having excessive high transmittance to affect the accuracy of pattern transfer. According to an embodiment of the present disclosure, the peripheral portion 208 has a transmittance T11, and the following condition may be satisfied: 70%≤T11≤80%. The transmittance T11 of the peripheral portion 208 may be equal to or substantially equal to the transmittance T2 of the second pattern region 214 and/or the transmittance T3 of the third pattern region 224.

In FIG. 5, since the predetermined patterns 210 are not disposed in the first pattern region 204 evenly, the optical assist members 250 may also be disposed in the main pattern portion 206 to prevent an excessive difference between the transmittance of the portion with denser predetermined patterns 210 and the transmittance of the portion with sparse predetermined patterns 210.

Similarly, the second pattern region 214 may be further divided into a main pattern portion 216 and a peripheral portion 218 respectively corresponding to the main device portion 316 and the peripheral portion 318 of the memory region 314. The peripheral portion 218 surrounds the main pattern portion 216. The pattern density of the main pattern portion 216 may be equal to the pattern density of the peripheral portion 218. Specifically, when the second pattern region 214 includes both the main pattern portion 216 and the peripheral portion 218, the aforementioned transmittance T2 of the second pattern region 214 refers to the transmittance of the main pattern portion 216. In this embodiment, the optical assist members 250 are also disposed in the peripheral portion 218 for adjusting the transmittance of the peripheral portion 218, so as to prevent the peripheral portion 218 from having excessive high transmittance to affect the accuracy of pattern transfer. According to an embodiment of the present disclosure, the peripheral portion 218 has a transmittance T21, and the following condition may be satisfied: 70%≤T21≤80%. According to an embodiment of the present disclosure, the transmittance T21 of the peripheral portion 218 may be equal to or substantially equal to the transmittance (i.e., the transmittance T2) of the main pattern portion 216.

Similarly, the third pattern region 224 may be further divided into a main pattern portion 226 and a peripheral portion 228 respectively corresponding to the main device portion 326 and the peripheral portion 328 of the second device region 324. The peripheral portion 228 surrounds the main pattern portion 226. The pattern density of the main pattern portion 226 may be equal to the pattern density of the peripheral portion 228. Specifically, when the third pattern region 224 includes both the main pattern portion 226 and the peripheral portion 228, the aforementioned transmittance T3 of the third pattern region 224 refers to the transmittance of the main pattern portion 226. In this embodiment, the optical assist members 250 are also disposed in the peripheral portion 228 for adjusting the transmittance of the peripheral portion 228, so as to prevent the peripheral portion 228 from having excessive high transmittance to affect the accuracy of pattern transfer. According to an embodiment of the present disclosure, the peripheral portion 228 has a transmittance T31, and the following condition may be satisfied: 70%≤T31≤80%. According to an embodiment of the present disclosure, the transmittance T31 of the peripheral portion 228 may be equal to or substantially equal to the transmittance (i.e., the transmittance T3) of the main pattern portion 226.

According to the above description, in the present disclosure, the transmittance of each of the regions of the photomask 20 may be adjusted by disposing the optical assist members 250, while the patterns of the optical assist members 250 will not be transferred to the photoresist layer 360. Therefore, the shapes, locations and arrangements of the optical assist member 250 capable of achieving the aforementioned two functions are all within the scope of the present disclosure. In FIG. 5, the optical assist members 250 are arranged along the horizontal direction D1 or D2, which is for the convenience of drawing, and the present disclosure is not limited thereto. Furthermore, as shown in FIG. 5, a single optical assist member 250 may span different regions.

As shown in FIG. 5, each of the predetermined patterns 210 may have an extending direction, and the extending direction of each of the predetermined patterns 210 may be the direction that the predetermined pattern 210 has a longest length. Herein, the extending direction of each of the predetermined patterns 210 is exemplarily parallel to the horizontal direction D1. Each of the optical assist members 251 disposed in the main pattern portion 216 of the second pattern region 214 may have an extending direction, and the extending direction of each of the optical assist members 251 may be the direction that the optical assist member 251 has a longest length. Herein, the extending direction of each of the optical assist members 251 is exemplarily parallel to the horizontal direction D2. Each of the optical assist members 252 disposed in the main pattern portion 226 of the third pattern region 224 may have an extending direction, and the extending direction of each of the optical assist members 252 may be the direction that the optical assist member 252 has a longest length. Herein, the extending direction of each of the optical assist members 252 is exemplarily parallel to the horizontal direction D2. The extending direction of each of the predetermined patterns 210 is preferably perpendicular to the extending direction of each of the optical assist members 251, and the extending direction of each of the predetermined patterns 210 is preferably perpendicular to the extending direction of each of the optical assist members 252.

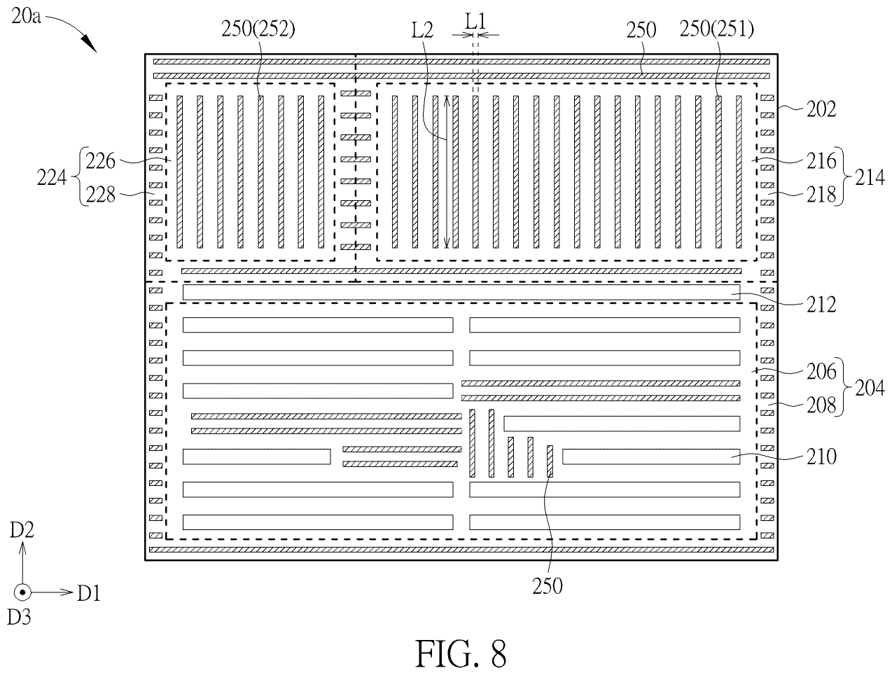

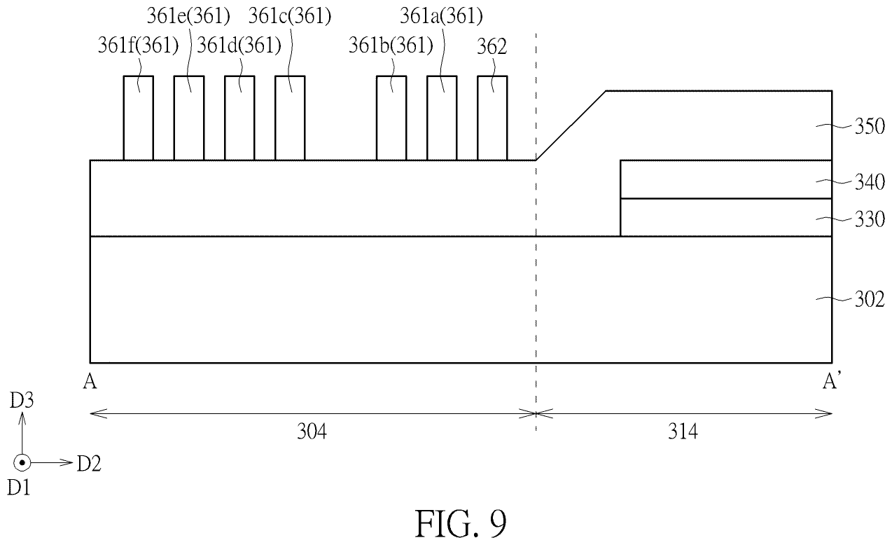

Please refer to FIG. 8 and FIG. 9 at the same time. FIG. 8 is a schematic top view showing a photomask 20a according to another embodiment of the present disclosure. FIG. 9 is a schematic cross-sectional view showing a step of a method for transferring a pattern according to another embodiment of the present disclosure. FIG. 9 corresponds to the process stage of FIG. 6. The main difference between the photomask 20a and the photomask 20 is that the photomask 20a further includes a dummy pattern 212 disposed in the peripheral portion 208, and performing the exposure and development process includes transferring the dummy pattern 212 to the photoresist layer 360. As shown in FIG. 9, a patterned photoresist 362 may be formed on the target material layer 350, and the patterned photoresist 362 corresponds to the dummy pattern 212. Next, the target material layer 350 located below the patterned photoresists 361 and 362 may be patterned with the patterned photoresists 361 and 362 being etching masks, so as to form patterned target materials (not shown) corresponding to the patterned photoresists 361 and 362 in the first device region 304. The patterned target materials corresponding to the patterned photoresists 361 serve as gates, and the patterned target material corresponding to the patterned photoresist 362 serves as a dummy gate.

As shown in FIG. 8 to FIG. 9, in the present disclosure, the transmittance of the first pattern region 204 may also be adjusted through the dummy pattern 212. The difference between the dummy pattern 212 and the optical assist member 250 is that the pattern of the dummy pattern 212 will be transferred to the photoresist layer 360 and will be further transferred to the target material layer 350. Since the portions of the target material layer 350 in the memory region 314 and the second device region 324 are required to be removed, the dummy pattern 212 is not applicable for the second pattern region 214 and the third pattern region 224.

Compared with the prior art, in the present disclosure, the transmittance of each of the regions of the photomask may be adjusted by disposing the optical assist members, while the patterns of the optical assist members will not be transferred to the photoresist layer and the target material layer. Thereby, it is beneficial to improve the accuracy of pattern transfer of the predetermined patterns at the periphery of the region where the predetermined pattern is disposed, and it is beneficial to improve the performance and/or yield of the patterned semiconductor device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A photomask, configured to corporate with an exposure source to pattern a semiconductor device, the semiconductor device defining a first device region and a memory region disposed adjacent to the first device region, the semiconductor device comprising a memory device disposed in the memory region, the photomask comprising:
a base, defining a first pattern region and a second pattern region respectively corresponding to the first device region and the memory region;
a predetermined pattern disposed in the first pattern region; and
a first optical assist member disposed in the second pattern region, wherein a pattern density of the first pattern region is greater than a pattern density of the second pattern region, and a dimension of the first optical assist member is less than an exposure limit of the exposure source.

2. The photomask of claim 1, wherein the first pattern region has a transmittance T1, the second pattern region has a transmittance T2, and a following condition is satisfied:
1<T2/T1≤1.15.

3. The photomask of claim 1, wherein the base has an initial transmittance T0, the second pattern region has a transmittance T2, and a following condition is satisfied:
20%≤T0−T2≤30%.

4. The photomask of claim 1, wherein the second pattern region has a transmittance T2, and a following condition is satisfied:
70%≤T2≤80%.

5. The photomask of claim 1, wherein a length of the first optical assist member in a direction is greater than 0 and less than or equal to 24 nm.

6. The photomask of claim 1, wherein the first pattern region comprises a main pattern portion and a peripheral portion surrounding the main pattern portion, and a pattern density of the main pattern portion is greater than a pattern density of the peripheral portion.

7. The photomask of claim 6, further comprising:
a dummy pattern disposed in the peripheral portion.

8. The photomask of claim 6, wherein the peripheral portion has a transmittance T11, and a following condition is satisfied:
70%≤T11≤80%.

9. The photomask of claim 6, further comprising:
a second optical assist member disposed in the main pattern portion.

10. The photomask of claim 1, wherein the base further defines a third pattern region disposed adjacent to the first pattern region and corresponding to a second device region of the semiconductor device, the first device region is a low voltage device region, and the second device region is a medium and high voltage device region.

11. A method for transferring a pattern, comprising:
providing a semiconductor device defining a first device region and a memory region disposed adjacent to the first device region, wherein the semiconductor device comprises a memory device and a target material layer, the memory device is disposed in the memory region, the target material layer is disposed in the first device region and the memory region, and the target material layer is located above the memory device;
forming a photoresist layer on the target material layer;
providing a photomask between the photoresist layer and an exposure source, wherein the photomask comprises a base, a predetermined pattern and a first optical assist member, the base defines a first pattern region and a second pattern region respectively corresponding to the first device region and the memory region, the predetermined pattern is disposed in the first pattern region, the first optical assist member is disposed in the second pattern region, a pattern density of the first pattern region is greater than a pattern density of the second pattern region, and a dimension of the first optical assist member is less than an exposure limit of the exposure source; and
performing an exposure and development process, wherein the predetermined pattern of the photomask is transferred to the photoresist layer.

12. The method of claim 11, wherein the first pattern region has a transmittance T1, the second pattern region has a transmittance T2, and a following condition is satisfied:
1<T2/T1≤1.15.

13. The method of claim 11, wherein the base has an initial transmittance T0, the second pattern region has a transmittance T2, and a following condition is satisfied:
20%≤T0−T2≤30%.

14. The method of claim 11, wherein the second pattern region has a transmittance T2, and a following condition is satisfied:
70%≤T2≤80%.

15. The method of claim 11, wherein a length of the first optical assist member in a direction is greater than 0 and less than or equal to 24 nm.

16. The method of claim 11, wherein the first pattern region comprises a main pattern portion and a peripheral portion surrounding the main pattern portion, and a pattern density of the main pattern portion is greater than a pattern density of the peripheral portion.

17. The method of claim 16, wherein the photomask further comprises a dummy pattern disposed in the peripheral portion, and performing the exposure and development process comprises transferring the dummy pattern to the photoresist layer.

18. The method of claim 16, wherein the photomask further comprises a second optical assist member disposed in the main pattern portion.

19. The method of claim 11, wherein the base further defines a third pattern region disposed adjacent to the first pattern region and corresponding to a second device region of the semiconductor device, the first device region is a low voltage device region, and the second device region is a medium and high voltage device region.

20. The method of claim 11, wherein a portion of the target material layer in the memory region protrudes relative to a portion of the target material layer in the first device region.
